(19) United States
(12) Patent Application Publication
(10) Pub. No.: US 2013/0248878 A1
(43) Pub. Date: Sep. 26, 2013

(54) METHOD FOR MANUFACTURING NITRIDE SEMICONDUCTOR DEVICE AND THE SAME MANUFACTURED THEREOF

(71) Applicants: Taehoon Jang, Seoul (KR); Youngshin Eum, Seoul (KR)

(72) Inventors: Taehoon Jang, Seoul (KR); Youngshin Eum, Seoul (KR)

(73) Assignee: LG Electronic Inc., Seoul (KR)

(21) Appl. No.: 13/991,070

(22) PCT Filed: Nov. 15, 2011
(86) PCT No.: PCT/KR2011/008710

§ 371 Date: May 31, 2013

(30) Foreign Application Priority Data
Dec. 2, 2010 (KR) 10-2010-0121733

(51) Int. Cl. H01L 29/80; H01L 29/66

(52) U.S. Cl. CPC H01L 29/802; H01L 29/66431
USPC 257/76; 438/191

(57) ABSTRACT

Disclosed is a nitride semiconductor device and a method for manufacturing the same and the method for manufacturing the nitride semiconductor device comprising: growing a buffer layer including a first semiconductor on a substrate; growing a first barrier layer including a second semiconductor different from the first semiconductor; forming an oxide film layer on a portion where a recess is to be formed; growing a second barrier layer including the second semiconductor; forming a recess by removing the oxide film layer; and forming a gate electrode on the recess.

### BACKGROUND OF THE DISCLOSURE

### Field of Endeavor

The teachings in accordance with exemplary and non-limiting embodiments of this disclosure relate generally to a semiconductor device, and more particularly to a HFET (Heterojunction Field-Effect Transistor) and a method for manufacturing the same.

### Background

In general, nitride-based semiconductors are wide bandgap compound semiconductors capable of emitting light ranging from visible light to ultraviolet light.

The nitride-based semiconductors applied to emit light such as blue purple light emitting diodes or laser diodes and blue light emitting diodes are already developed for wide use in light pick-up devices, traffic lights, public displays, liquid crystal backlight illuminations and mobile terminals.

Gallium nitride (GaN), one of representative materials for semiconductors, is being widely studied recently as a material for semiconductor devices due to its advantageous characteristics such as higher breakdown voltages and low on-resistances over those of silicon.

Meanwhile, as a high power element which is turned on without application of voltage to its gate, a MOSFET (Metal-Oxide-Semiconductor Field-Effect Transistor) and an IGBT (Insulated Gate Bipolar Transistor) are being focused, and an HEMT (High Electron Mobility Transistor) made of GaN semiconductors is also being studied.

Although an HFET (Heterojunction Field Effect Transistor) structure based on nitride semiconductors has high electron mobility for application in communication devices of harmonic characteristics, the HFET poses a problem of generating a so-called “normally-on” phenomenon due to its structural characteristics.

In general, there are largely two methods to achieve a normally-off characteristic that is required in a high power element. One is to deplete a 2DEG (2-Dimensional Electronic Gas) concentration to reduce an off-state (−) voltage. This method however poses a problem of resulting in decrease a maximum drain current at an on-state due to reduction in the 2DEG concentration serving as a channel.

The second method is a recess gate structure that allows a depletion region to be rapidly diffused to a channel by etching a gate to narrow a distance of the gate which has a Schottky junction with the channel. That is, in order to achieve the normally-off characteristic, a gate electrode is etched to narrow a distance to the channel and to increase a turn-on voltage to a (+) direction.

However, the disadvantage is that the HFET structure essentially requires a several nm etching depth control because an increased characteristic of turn-on voltage is sensitive in response to a distance between a gate and a channel.

Another disadvantage is that a surface state is not good due to etching damages to increase a surface trap concentration, whereby a Schottky characteristic with a gate electrode deteriorates.

Still further disadvantage is that the Schottky characteristic also changes that is sensitive to the surface damages, making it difficult to be applied to mass production as current-voltage characteristics such as turn-on voltage and current leakage greatly change in response to types of etching gases and treatment methods.

### SUMMARY OF THE DISCLOSURE

Exemplary aspects of the present disclosure are to substantially solve at least the above problems and/or disadvantages and to provide at least the advantages as mentioned below. Thus, the present disclosure is directed to provide a nitride semiconductor device configured to enable a several-nm control by manufacturing a device using a growth without recourse to etching process, and a method for manufacturing the same.

The present disclosure is also directed to provide a nitride semiconductor device configured to greatly reduce a leakage current due to less trap concentration by manufacturing a recess-arranged gate electrode using growth, and a method for manufacturing the same.

In one general aspect of the present disclosure, there may be provided a nitride semiconductor device, the device comprising: a buffer layer including a first semiconductor; a first barrier layer disposed on the buffer layer, the first barrier layer including a second semiconductor different from the first semiconductor; a second barrier layer including the second semiconductor to form a recess on the first barrier layer; and a gate electrode on the recess.

In some exemplary embodiments, the device may further comprise a capping layer on the second barrier layer to reduce a leakage current.

In some exemplary embodiments, the device may further comprise a source electrode and a drain electrode on the second barrier layer.

In some exemplary embodiments, the first semiconductor may include a GaN.

In some exemplary embodiments, the second semiconductor may include an AlGaN.

In some exemplary embodiments, the capping layer may include a GaN or an AlN.

In some exemplary embodiments, the drain electrode may include any one of Ti, Al and Ni.

In some exemplary embodiments, the source electrode and the drain electrode may have a stacked structure of Ti, Al, Ti and Au.

In other general aspect of the present disclosure, there may be provided a method for manufacturing a nitride semiconductor device, the method comprising: growing a buffer layer including a first semiconductor on a substrate; growing a first barrier layer including a second semiconductor different from the first semiconductor; forming an oxide film layer on a portion where a recess is to be formed; growing a second barrier layer including the second semiconductor; forming a recess by removing the oxide film layer; and forming a gate electrode on the recess.

In some exemplary embodiments, the method may further comprise growing a capping layer reducing a leakage current on the second barrier layer.

In some exemplary embodiments, the method may further comprise forming a source electrode and a drain electrode on the second barrier layer.

In some exemplary embodiments, a height of the oxide film layer may be substantially same as or lower than a height of the recess to be formed.

In some exemplary embodiments, the oxide film layer may include a SiO₂

In some exemplary embodiments, the buffer layer, the first barrier layer, the second barrier layer and the capping layer may be grown using an MOCVD (Metal Organic Chemical Vapor Deposition).

In some exemplary embodiments, the oxide film layer may be formed by photo-resist and etching.

Exemplary aspects of the present disclosure have an advantageous effect in that devices are manufactured using a growth without recourse to etching process to enable a several-nanometer control.

Another advantageous effect is that a leakage current on a surface can be greatly reduced due to less trap concentration by manufacturing a surface of a gate electrode arranged on a recess.

Still another advantageous effect is that a voltage resistance characteristic which is one of important characteristics as a high power element can be improved and a driving voltage can be easily controlled.

### BRIEF DESCRIPTION OF THE DRAWINGS

The teachings of the present disclosure can be readily understood by considering the following detailed description in conjunction with the accompanying drawings, in which:

FIG. 1 is a cross-sectional view illustrating a nitride semiconductor device according to an exemplary embodiment of the present disclosure; and

FIGS. 2a to 2e are cross-sectional views sequentially illustrating a method for manufacturing a nitride semiconductor device according to exemplary embodiment of the present disclosure.

### DETAILED DESCRIPTION OF THE INVENTION

Various exemplary embodiments will be described more fully hereinafter with reference to the accompanying drawings, in which some exemplary embodiments are shown.

The present inventive concept may, however, be embodied in many different forms and should not be construed as limited to the example embodiments set forth herein. Rather, the described aspect is intended to embrace all such alterations, modifications, and variations that fall within the scope and novel idea of the present disclosure.

It will be understood that, although the terms first, second etc. may be used herein to describe various elements, components, regions, layers and/or sections, these elements, components, regions, layers and/or sections should not be limited by these terms.

These terms are only used to distinguish one element, component, region, layer or section from another region, layer or section. Thus, a first element, component, region, layer or section discussed below could be termed a second element, component, region, layer or section without departing from the teachings of the present inventive concept.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout.

As used herein, the singular forms “a,” “an” and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that like numbers refer to like elements throughout. In the figures, certain layers, sizes, shapes, components or features may be exaggerated for clarity and convenience.

Now, the present invention will be described in detail with reference to the accompanying drawings. Like numbers refer to like elements throughout and explanations that duplicate one another will be omitted.

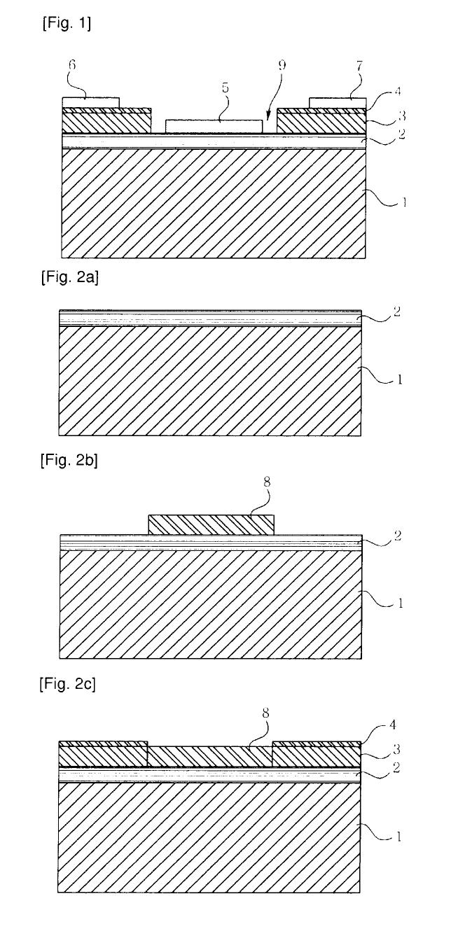

FIG. 1 is a cross-sectional view illustrating a nitride semiconductor device according to an exemplary embodiment of the present disclosure.

Referring to FIG. 1, a nitride semiconductor manufactured by a method for manufacturing a nitride semiconductor device according to an exemplary embodiment of the present disclosure comprises a buffer layer 1, a first barrier layer 2, a second barrier layer 3, a capping layer 4, a gate electrode 5, a source electrode 6 and a drain electrode 7.

A nitride semiconductor manufactured by the method according to the present disclosure has a normally-off type HFET (Heterojunction Field Effect Transistor) having a typical recess structure, where the gate electrode 5 is arranged inside a recess 9 formed by the second barrier layer 3 and the capping layer 4.

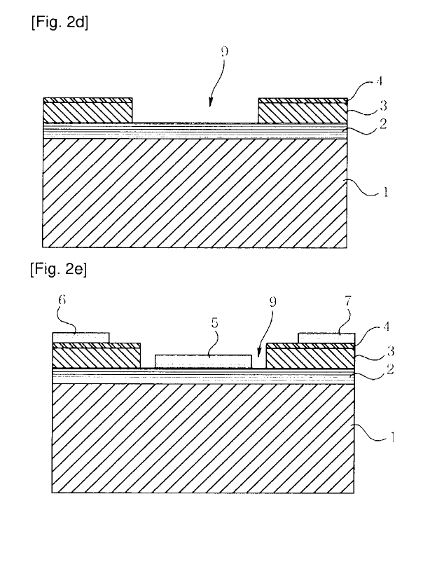

Now, a detailed configuration of the nitride semiconductor manufactured by the method according to the present disclosure will be described with reference to FIGS. 2a to 2e. FIGS. 2a to 2e are cross-sectional views sequentially illustrating a method for manufacturing a nitride semiconductor device according to exemplary embodiment of the present disclosure.

First, although not illustrated in the drawings, a substrate for growing a semiconductor device is prepared. The substrate may be manufactured by a material such as sapphire, Si, SiC (silicon carbide) or GaN (gallium nitride).

Referring to FIG. 2a, a buffer layer 1 including a first semiconductor is grown on an upper surface of the substrate. Although the buffer layer 1 preferably includes GaN, the present disclosure is not limited thereto. Although the buffer layer 1 is preferably grown by a MOCVD (Metal Organic Chemical Vapor Deposition), the present disclosure is not limited thereto.

In a case the buffer layer 1 is formed with GaN, an epitaxial growth is preferably performed by combining TRGa (TrimethylGallium) and NH3 (Ammonia) at a high temperature in a reactor. However, the present disclosure is not limited thereto. At this time, a thickness of the buffer layer 1 is 0.5 μm˜1.0 μm, and preferably 0.6 μm˜3.0 μm.

Thereafter, as illustrated again in FIG. 2a, the first barrier layer 2 including a second semiconductor is grown. Although the first barrier layer 2 includes AlGaN (Aluminium Gallium Nitride), the present disclosure is not limited thereto.

In a case the first barrier layer 2 is formed with AlGaN, a composition of aluminium is 1˜100%, and preferably 10˜50%. Furthermore, a thickness is 0 μm˜100 μm, and preferably 1 μm˜10 μm.

In the manufacturing method according to the present disclosure, although the first barrier layer 2 is also grown by the MOCVD, the present disclosure is not limited thereto.

The MOCVD is appropriate for the present disclosure because it can adjust a growth rate, and a growth speed is slow enough to control to a nanometer level.

A 2DEG layer (not shown) is formed between the buffer layer 1 and the first barrier layer 2 by the growth of the first barrier layer 2, which is a phenomenon due to a bandgap of materials between the buffer layer 1 and the first barrier layer 2 being different, the detailed description of which will be omitted as it is well known to the skilled in the art.

Referring to FIG. 2a, a substrate is cleaned after the first barrier layer 2 is grown to a predetermined height as per the design.

Then, as illustrated in FIG. 2b, an oxide film layer 8 is formed on a portion where the gate electrode 5 is formed for restricting the growth of the first barrier layer 2 using a photo-resist and etching. The oxide film layer 8 functions as a mask for selective growth.

The oxide film layer 8 is preferably grown with a thickness same as or a little thinner than a height for forming a recess 9. Although the thickness of the oxide film layer 8 is preferably 50 nm˜1000 nm as there is no re-growth above the oxide film layer 8, the present disclosure is not limited thereto. Furthermore, the oxide film layer 8 is preferably formed with SiO₂ for easy removal, the present disclosure is not limited thereto.

Successively, as illustrated in FIG. 2c, the second barrier layer 3 is grown. Although the second barrier layer 3 preferably includes AlGaN as in the first barrier layer 2, the present disclosure is not limited thereto. The second barrier layer 3 is also preferably grown by the MOCVD; the present disclosure is not limited thereto.

In a case the second barrier layer 3 is formed with AlGaN, a composition of aluminium may be same as that of the first barrier layer 2, or may be 5˜100%. Although a thickness of the second barrier layer 3 is preferably 1 nm˜100 nm, the present disclosure is not limited thereto.

Hence, the method for manufacturing the nitride semiconductor device is configured such that the second barrier layer 3 is grown with a thickness a bit thinner than the height for forming the recess 9. Referring to the drawings, it can be noticed that a sum of a height of the second barrier layer 3 and a height of the capping layer 4 is a height for forming the recess 9. Referring to FIG. 2c, although the second barrier layer 3 is grown with a height same as that of the oxide film layer 8, the present disclosure is not limited thereto. Alternatively, the height of the second barrier layer 3 added by the height of the capping layer 4 may be same as that of the oxide film layer 8.

After growth of the second barrier layer 3, the capping layer 4 may be grown as illustrated in FIG. 2c to reduce a leakage current. Although the capping layer 4 is preferably formed with GaN or AlN, the present disclosure is not limited thereto. The thickness is preferably less than 100 nm; the present disclosure is not limited thereto.

In a case the capping layer 4 is formed with AlN, a composition of aluminium may be 0˜100%, preferably be 50˜100%. The capping layer 3 is also preferably grown by the MOCVD; the present disclosure is not limited thereto.

After the capping layer 4 is grown as described above, the oxide film layer 8 is removed as illustrated in FIG. 2d. The recess 9 is formed by removal of the oxide film layer 8.

Then, as illustrated in FIG. 2e, the gate electrode 5, the source electrode 6 and the drain electrode 7 are deposited. That is, the gate electrode 5 is formed on the recess 9, while the source electrode 6 and the drain electrode 7 are formed on a convex portion other than the recess 9. That is, the source electrode 6 and the drain electrode 7 are formed on a region where the second barrier layer 3 and the capping layer 4 are formed to preferably form an ohmic contact.

The source electrode 6 and the drain electrode 7 may be a stacked structure of Ti, Al, Ti and Au, for example. Although thickness of each metal is preferably 30, 100, 20 and 200 nm, the present disclosure is not limited thereto. The source electrode 6 and the drain electrode 7 may be deposited using e-beam, and patterns may be formed using a lift-off process.

Although the gate electrode 5 formed on a region removed of the oxide film layer 8, i.e., the recess 9, preferably includes a metal of high work function such as Ti, Al or Ni, for example, the present disclosure is not limited thereto.

Although the present disclosure has been described with reference to a number of illustrative embodiments thereof, it should be understood that numerous other modifications and embodiments can be devised by those skilled in the art that will fall within the spirit and scope of the principles of this disclosure.

What is claimed is:

1. A nitride semiconductor device, the device comprising:
a buffer layer including a first semiconductor;
a first barrier layer disposed on the buffer layer, the first barrier layer including a second semiconductor different from the first semiconductor;
a second barrier layer including the second semiconductor to form a recess on the first barrier layer; and
a gate electrode on the recess.

2. The device of claim 1, further comprising:
a capping layer on the second barrier layer to reduce a leakage current.

3. The device of claim 1, further comprising:
a source electrode and a drain electrode on the second barrier layer.

4. The device of claim 1, wherein the first semiconductor includes a GaN.

5. The device of claim 1, wherein the second semiconductor includes an AlGaN.

6. The device of claim 2, wherein the capping layer includes a GaN or an AlN.

7. The device of claim 1, wherein the drain electrode includes any one of Ti, Al and Ni.

8. The device of claim 3, wherein the source electrode and the drain electrode has a stacked structure of Ti, Al, Ti and Au.

9. A method for manufacturing a nitride semiconductor device, the method comprising:
growing a buffer layer including a first semiconductor on a substrate;
growing a first barrier layer including a second semiconductor different from the first semiconductor;
forming an oxide film layer on a portion where a recess is to be formed;
growing a second barrier layer including the second semiconductor;
forming a recess by removing the oxide film layer; and
forming a gate electrode on the recess.

10. The method of claim 9, further comprising:
growing a capping layer reducing a leakage current on the second barrier layer.

11. The method of claim 9 or 10, further comprising:
forming a source electrode and a drain electrode on the second barrier layer.

12. The method of claim 9, wherein a height of the oxide film layer is substantially same as or lower than a height of the recess to be formed.

13. The method of claim 9, wherein the oxide film layer includes a SiO₂.

14. The method of claim 10, wherein the buffer layer, the first barrier layer, the second barrier layer and the capping layer are grown using an MOCVD (Metal Organic Chemical Vapor Deposition).

15. The method of claim 9, wherein the oxide film layer is formed by photo-resist and etching.
